(19) United States
(12) Patent Application Publication
(10) Pub. No.: US 2024/0321912 A1
(43) Pub. Date: Sep. 26, 2024

(54) SOLID-STATE IMAGING ELEMENT, MANUFACTURING METHOD, AND ELECTRONIC EQUIPMENT

(71) Applicant: SONY SEMICONDUCTOR SOLUTIONS CORPORATION, KANAGAWA (JP)

(72) Inventor: KAITO YOKOCHI, KANAGAWA (JP)

(21) Appl. No.: 18/577,717

(22) PCT Filed: Mar. 1, 2022
(86) PCT No.: PCT/JP2022/008490

§ 371 Date: Jan. 9, 2024

(30) Foreign Application Priority Data
Jul. 27, 2021 (JP) 2021-122207

(51) Int. Cl. H01L 27/146

(52) U.S. Cl. CPC H01L 27/14621; H01L 27/14623; H01L 27/1463; H01L 27/14645; H01L 27/14685

(57) ABSTRACT

The present disclosure relates to a solid-state imaging element, a manufacturing method, and electronic equipment capable of further improving performance. The solid-state imaging element includes a semiconductor substrate having a photoelectric conversion section provided for each pixel and a filter layer provided on a light-receiving side of the semiconductor substrate. In the filter layer, a filter whose surface shape is formed in a convex shape is provided for each pixel, and an inter-pixel light shielding section including a low-refractive index material having the refractive index lower than that of the filter is provided between the pixels. Then, the surfaces of the filters are formed in a convex shape by forming the filters on base materials that are provided in a pattern smaller than a pixel pitch by coating such that the filters are convex relative to an insulating film formed on the surface of the semiconductor substrate. The present technology is applicable, for example, to CMOS image sensors.

### TECHNICAL FIELD

The present disclosure relates to a solid-state imaging element, a manufacturing method, and electronic equipment, and more particularly, to a solid-state imaging element, a manufacturing method, and electronic equipment capable of further improving performance.

### BACKGROUND ART

Up until now, a structure having an on-chip lens on each pixel has been adopted in solid-state imaging elements such as CMOS (Complementary Metal Oxide Semiconductor) image sensors to improve light concentration efficiency.

Incidentally, it is only possible for a structure that concentrates light by using a lens to concentrate light only up to a light diffraction limit (approximately to a wavelength), which causes light to spread out because of diffraction after the concentration. Therefore, there is a concern that, if a focal point of the on-chip lens moves to a front side as pixel miniaturization progresses, color mixture may become more likely to occur in microscopic pixels of a size close to the wavelength of light to be concentrated than in large pixels as a result of spread of light because of diffraction after the concentration. For such a reason, a structure with an on-chip lens having as small a height as possible, a structure with no on-chip lens, and the like have been proposed as measures to prevent occurrence of such color mixture.

For example, PTL 1 proposes an imaging element that suppresses color mixture by adopting a structure with no on-chip lens, providing, between the pixels, partitions including a transparent material having a lower refractive index than color filters and forming the partitions in a tapered shape on a light incident side.

### CITATION LIST

### Patent Literature

### [PTL 1]

Japanese Patent Laid-open No. 2013-156463

### SUMMARY

### Technical Problem

Incidentally, in the structure with no on-chip lens as disclosed in the above PTL 1, color mixture increased and quantum efficiency QE decreased because of transmission of light through the partitions (transparent material having a low refractive index) provided between the pixels. For this reason, there is a demand to improve performance of imaging elements by reducing the occurrence of the color mixture and increasing the quantum efficiency QE.

The present disclosure has been devised in light of such circumstances, and it is an object thereof to further improve performance.

### Solution to Problem

A solid-state imaging element of one aspect of the present disclosure includes a semiconductor substrate having a photoelectric conversion section provided for each pixel and a filter layer provided on a light-receiving side of the semiconductor substrate, and, in the filter layer, a filter whose surface shape is formed in a curved shape is provided for each of the pixels, and an inter-pixel light shielding section including a low-refractive index material having a refractive index lower than that of the filter is provided between the pixels.

A manufacturing method of one aspect of the present disclosure is a manufacturing method of a solid-state imaging element including a semiconductor substrate having a photoelectric conversion section provided for each pixel and a filter layer provided on a light-receiving side of the semiconductor substrate and includes, in the filter layer, providing a filter whose surface shape is formed in a curved shape for each of the pixels and providing an inter-pixel light shielding section including a low-refractive index material having a refractive index lower than that of the filter between the pixels.

Electronic equipment of one aspect of the present disclosure includes a solid-state imaging element including a semiconductor substrate having a photoelectric conversion section provided for each pixel and a filter layer provided on a light-receiving side of the semiconductor substrate, in which, in the filter layer, a filter whose surface shape is formed in a curved shape is provided for each of the pixels, and an inter-pixel light shielding section including a low-refractive index material having a refractive index lower than that of the filter is provided between the pixels.

In one aspect of the present disclosure, in a filter layer provided on a light-receiving side of a semiconductor substrate having a photoelectric conversion section provided for each pixel, a filter whose surface shape is formed in a curved shape is provided for each pixel, and an inter-pixel light shielding section including a low-refractive index material having a refractive index lower than that of the filter is provided between the pixels.

### BRIEF DESCRIPTION OF DRAWINGS

FIG. 1 is a view illustrating a configuration example of a first embodiment of an imaging element to which the present technology is applied.

FIG. 2 is a cross-sectional view illustrating a configuration example of the imaging element with no on-chip lens and having a flat color filter surface shape.

FIG. 3 is a diagram describing reduction of color mixture.

FIG. 4 depicts views illustrating an application example of a first filter structure.

FIG. 5 depicts views illustrating an application example of a second filter structure.

FIG. 6 depicts views illustrating an application example of a third filter structure.

FIG. 7 depicts views illustrating an application example of a fourth filter structure.

FIG. 8 depicts views illustrating an application example of a fifth filter structure.

FIG. 9 depicts views illustrating an application example of a sixth filter structure.

FIG. 10 depicts views illustrating an application example of a seventh filter structure.

FIG. 11 depicts views illustrating a modification example of the imaging element.

FIG. 12 is a view describing a manufacturing method of the imaging element.

FIG. 13 is a view describing the manufacturing method of the imaging element.

FIG. 14 is a view illustrating a configuration example of a second embodiment of the imaging element to which the present technology is applied.

FIG. 15 depicts views illustrating an application example of a Bayer pattern filter structure.

FIG. 16 is a view describing a manufacturing method of the imaging element.

FIG. 17 is a view describing the manufacturing method of the imaging element.

FIG. 18 is a block diagram illustrating a configuration example of an imaging apparatus.

FIG. 19 is a diagram illustrating a usage example of using an image sensor.

### DESCRIPTION OF EMBODIMENT

Specific embodiments to which the present technology is applied will be described in detail below with reference to drawings.

### <First Configuration Example of the Imaging Element>

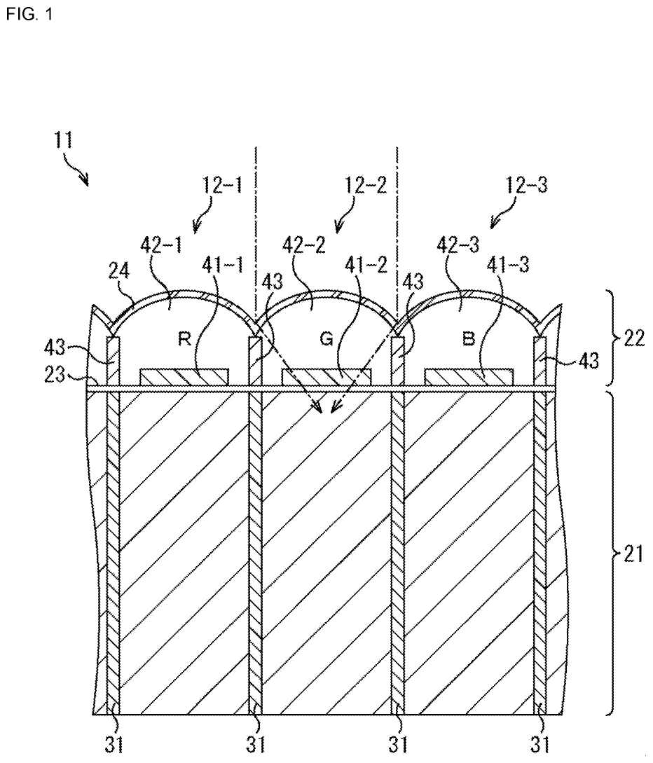

FIG. 1 is a view illustrating a configuration example of a first embodiment of an imaging element to which the present technology is applied.

An imaging element 11 includes a plurality of pixels 12 arranged in an array pattern, and FIG. 1 illustrates a cross-sectional configuration example of three pixels 12-1 to 12-3. For example, the pixel 12-1 receives red light, the pixel 12-2 receives green light, and the pixel 12-3 receives blue light. Hereinafter, the pixels 12-1 to 12-3 will be simply referred to as the pixels 12 in a case where it is not necessary to distinguish therebetween.

As illustrated in FIG. 1, the imaging element 11 includes a filter layer 22 stacked on a light-receiving side of a semiconductor substrate 21. Also, an insulating film 23 is formed on a surface of the semiconductor substrate 21, and an anti-reflection film 24 is formed on the surface of the filter layer 22.

The semiconductor substrate 21 is, for example, a thinly sliced monocrystal silicon wafer, and a photoelectric conversion section, which is not illustrated, is provided for each pixel 12. Also, in the semiconductor substrate 21, element isolation sections 31 formed, for example, by filling with silicon dioxide (SiO2) are provided to isolate the adjacent pixels 12 optically and electrically. It should be noted that air may be used as the element isolation sections 31 and that it is possible to adopt a hollow structure between the pixels 12 in the semiconductor substrate 21.

The filter layer 22 includes a base material 41 and a filter 42 provided for each pixel 12 and an inter-pixel light shielding section 43 provided between the adjacent pixels 12.

The base material 41 is provided independently for each pixel 12 in a pattern smaller than a pitch of the pixel 12 and so as to protrude relative to the insulating film 23 of the semiconductor substrate 21 at a center of the pixel 12. The base materials 41 are used to control the surface shapes of the filters 42 and are formed to a height of the inter-pixel light shielding section 43 or less. Also, a material having a refractive index equivalent to or lower than that of the semiconductor substrate 21 (silicon) and equal to or higher than that of the low-refractive index material of the inter-pixel light shielding sections 43 is used for the base materials 41 and includes, for example, a silicon dioxide film (refractive index n=1.46 at a wavelength of 530 nm). The filters 42 are stacked on the base materials 41, include resins including pigments appropriate to light to be received by the pixels 12, and transmit light of respective corresponding colors. For example, a filter 42-1 transmits red light, a filter 42-2 transmits green light, and a filter 42-3 transmits blue light.

The inter-pixel light shielding sections 43 include a low-refractive index material having a refractive index lower than that of the filters 42 and suppress color mixture between the pixels 12 in the filter layer 22. It should be noted that air may be used as the inter-pixel light shielding sections 43 and that it is possible to adopt a hollow structure between the filters 42.

In the imaging element 11 configured as described above, the surface shapes of the filters 42 are formed in a convex shape (in the shape of a condensing lens) by forming the insulating film 23 on the surface of the semiconductor substrate 21 first and then forming the base materials 41 having an independent pattern for each pixel 12 and coating the base materials 41 with the filters 42. Consequently, in the imaging element 11, light applied to the pixels 12 is concentrated by the filters 42. This makes it possible for the imaging element 11 to avoid decrease in light concentration efficiency even if no on-chip lens is provided.

Further, it is possible for the imaging element 11 to reduce the height of structures provided on top of or above the semiconductor substrate 21 by having no on-chip lens. Consequently, it is possible for the imaging element 11 to confine light inside the pixels 12 with high efficiency by using the inter-pixel light shielding sections 43 thanks to a low-height structure even if a focal point moves to a front side because of the filters 42 as miniaturization of the pixels 12 progresses. This makes it possible for the imaging element 11 to reduce the occurrence of color mixture and increase the quantum efficiency QE, which improves performance.

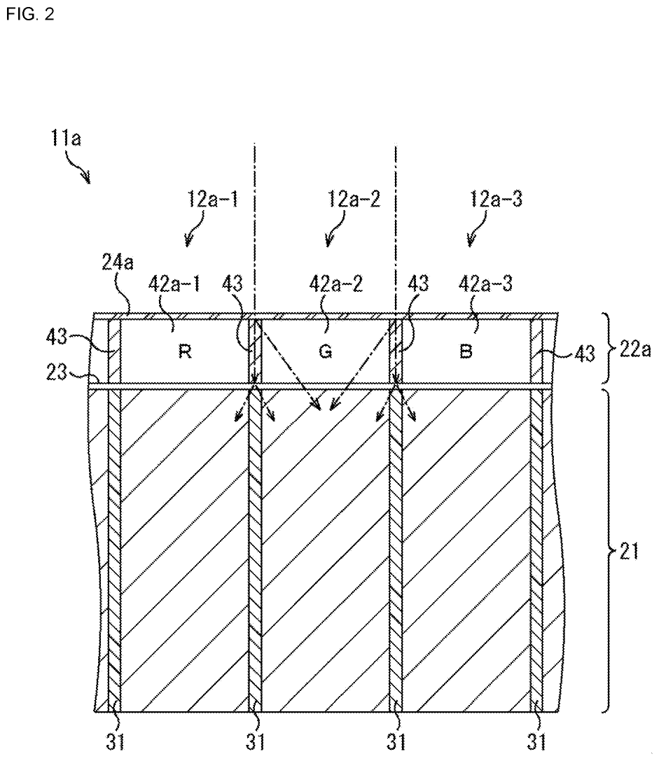

Here, as illustrated in FIG. 2, in an imaging element 11a having no on-chip lens and in which the surface shapes of filters 42a are formed in a flat shape, light transmits through the inter-pixel light shielding sections 43. That is, as illustrated by alternate long and short dash line arrows in FIG. 2, part of light heading toward the inter-pixel light shielding sections 43 transmits through the inter-pixel light shielding sections 43 and enters the semiconductor substrate 21, as a result of which there is a concern that occurrence of color mixture may increase and the quantum efficiency QE may decrease.

In contrast to the imaging element 11a having such a configuration, it is possible for the imaging element 11 in FIG. 1 to prevent light from transmitting through the inter-pixel light shielding sections 43 by forming the surface shapes of the filters 42 in a convex shape. That is, as illustrated by the alternate long and short dash line arrows in FIG. 1, light heading toward the inter-pixel light shielding sections 43 is refracted by the surfaces of the filters 42 and therefore suppressed from entering the inter-pixel light shielding sections 43, as a result of which it is possible for the imaging element 11 to reduce the occurrence of color mixture and increase the quantum efficiency QE.

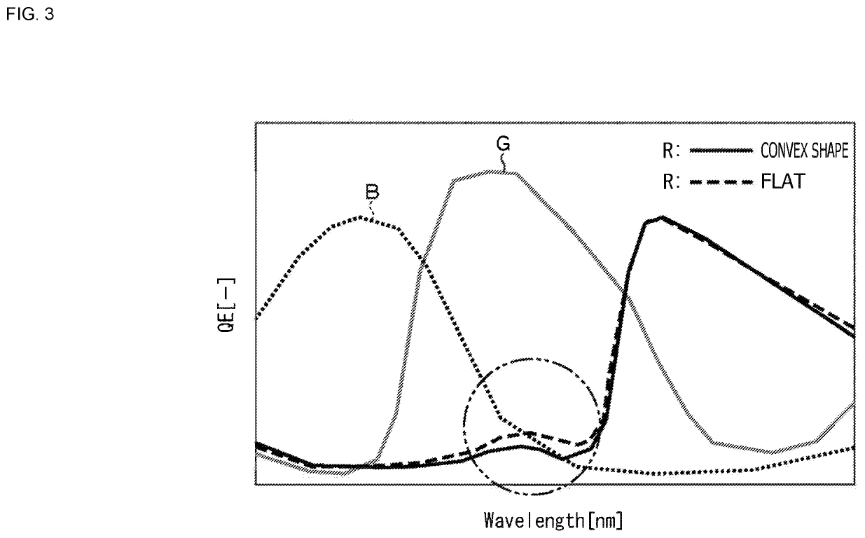

FIG. 3 is a view describing reduction of color mixture in the imaging element 11.

As illustrated in FIG. 3, the quantum efficiency QE of the pixel 12-1 that receives red (R) light in the imaging element 11 having the filters 42 whose surface shapes are formed in a convex shape and that of a pixel 12a-1 that receives red (R) light in the imaging element 11a having the filters 42a whose surface shapes are formed in a flat shape are compared.

For example, it is illustrated that, in a region surrounded by a circular alternate long and two short dashes line, that is, in a green light wavelength range, the quantum efficiency QE of the pixel 12-1 is reduced more than the quantum efficiency QE of the pixel 12a-1. That is, while green light is mixed in the pixel 12a-1 that receives red light (R) in the imaging element 11a, the mixture is suppressed in the imaging element 11.

In particular, there has been a tendency that the occurrence of color mixture increases in the imaging element 11a because of leakage of diagonally incident light into the adjacent pixels. In contrast, an incidence angle of diagonally incident light heading toward the inter-pixel light shielding sections 43 becomes shallower in the imaging element 11 than in the imaging element 11a, which causes that light to be totally reflected by the inter-pixel light shielding sections 43 and reduces the occurrence of color mixture even in the structure with no on-chip lens.

### <Application Examples of the Filter Structure>

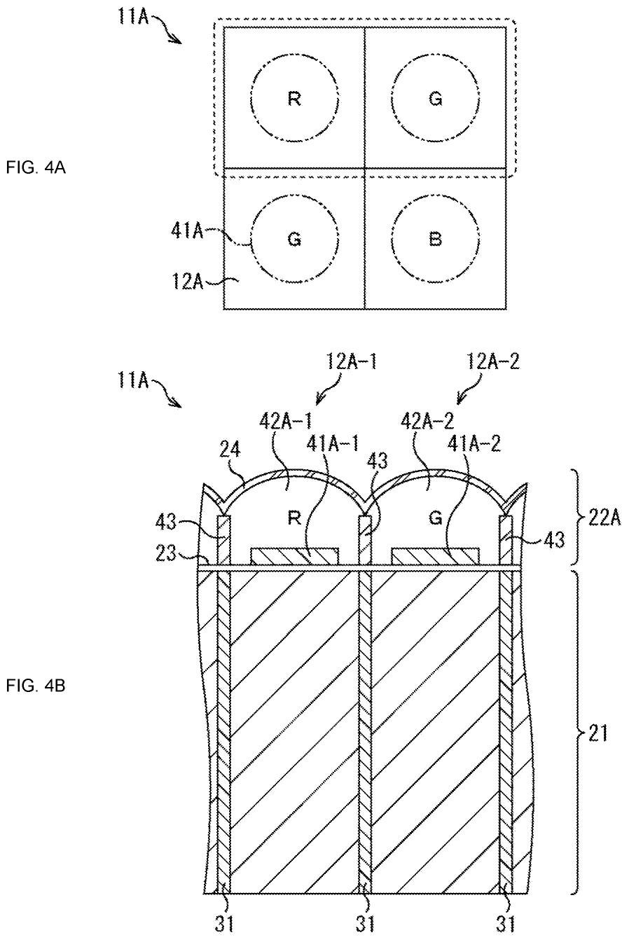

Application examples in which the structure of the imaging element 11 in FIG. 1 is applied to various filter structures will be described with reference to FIGS. 4 to 10. It should be noted that the same reference signs will be assigned to components common to those of the imaging element 11 in FIG. 1 in each of the following application examples and that detailed description thereof will be omitted.

FIG. 4 depicts views illustrating an application example in which the structure of the imaging element 11 in FIG. 1 is applied to a first filter structure. FIG. 4A illustrates a planar layout of an imaging element 11A, and FIG. 4B illustrates a cross-sectional configuration example of two pixels 12A-1 and 12A-2 surrounded by a dashed line illustrated in FIG. 4A.

As illustrated in FIG. 4, in the imaging element 11A, a filter layer 22A, which is a first filter structure, has filters 42A arranged in a pattern such that, of the two-by-two or four pixels 12A, the left top pixel 12A is red (R), the right top and left bottom pixels 12A are green (G), and the right bottom pixel 12A is blue (B), and this pattern of the two-by-two pixels 12A is repeated (what is called a Bayer pattern).

Also, in the imaging element 11A, as illustrated by an alternate long and two short dashes line in FIG. 4A, a base material 41A is formed at the center of each of the pixels 12A in a circular pattern smaller than the pixel pitch independently for each pixel 12A.

For example, in the imaging element 11A, it is possible to adopt a structure using silicon dioxide as the base materials 41A, air as the inter-pixel light shielding sections 43, and silicon dioxide as the element isolation sections 31.

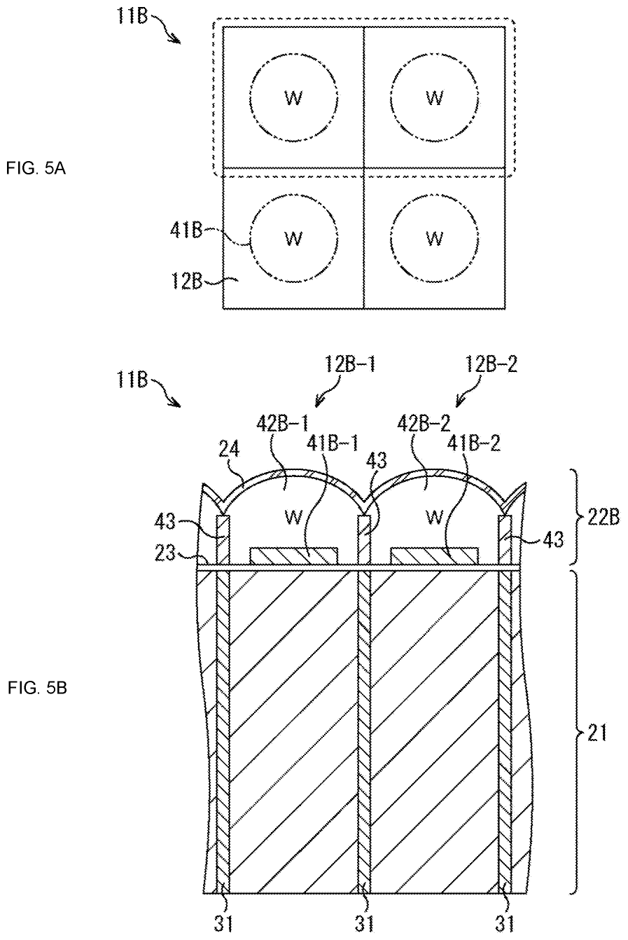

FIG. 5 depicts views illustrating an application example in which the structure of the imaging element 11 in FIG. 1 is applied to a second filter structure. FIG. 5A illustrates a planar layout of an imaging element 11B, and FIG. 5B illustrates a cross-sectional configuration example of two pixels 12B-1 and 12B-2 surrounded by a dashed line illustrated in FIG. 5A.

As illustrated in FIG. 5, in the imaging element 11B, a filter layer 22B, which is a second filter structure, has transparent (W) filters 42B that transmit light in an entire wavelength range arranged for all the pixels 12B. That is, the imaging element 11B to which the second filter structure is applied has what is called a monochrome structure that outputs a luminance value from all the pixels 12B.

Also, in the imaging element 11B, as illustrated by an alternate long and two short dashes line in FIG. 5A, a base material 41B is formed at the center of each of the pixels 12B in a circular pattern smaller than the pixel pitch independently for each pixel 12B.

For example, in the imaging element 11B, it is possible to adopt a structure using silicon dioxide as the base materials 41B, silicon nitride (SiN) as the transparent filters 42B, air as the inter-pixel light shielding sections 43, and silicon dioxide as the element isolation sections 31.

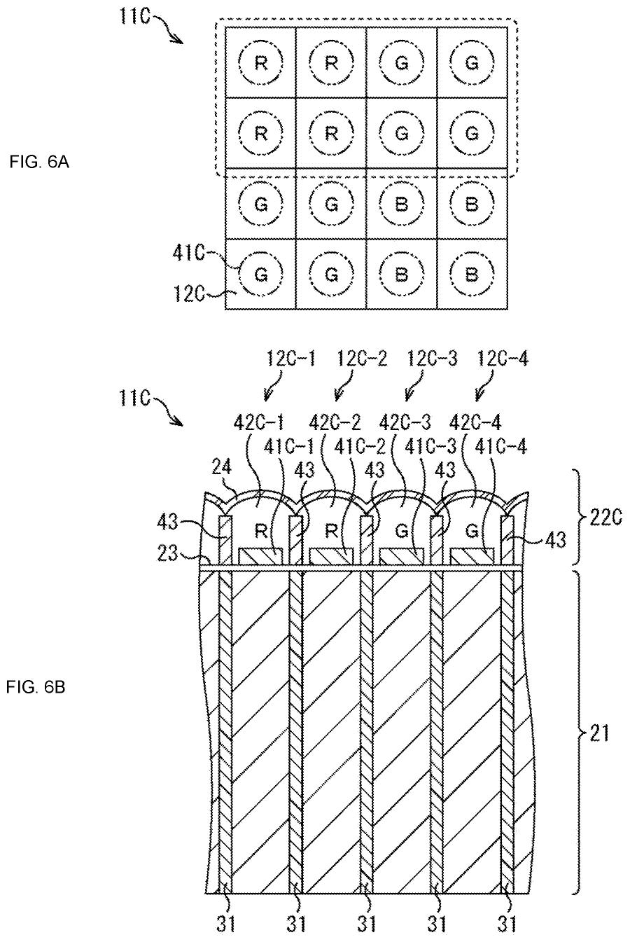

FIG. 6 depicts views illustrating an application example in which the structure of the imaging element 11 in FIG. 1 is applied to a third filter structure. FIG. 6A illustrates a planar layout of an imaging element 11C, and FIG. 6B illustrates a cross-sectional configuration example of four pixels 12C-1 to 12C-4 that are arranged side by side in one line of the eight pixels 12C surrounded by a dashed line illustrated in FIG. 6A.

As illustrated in FIG. 6, in the imaging element 11C, a filter layer 22C, which is a third filter structure, has filters 42C arranged in a pattern such that, of the four-by-four or 16 pixels 12C, the left top two-by-two pixels 12C are red (R), the right top and left bottom two-by-two pixels 12C are green (G), and the right bottom two-by-two pixels 12C are blue (B), and this pattern of the four-by-four pixels 12C is repeated.

Also, in the imaging element 11C, as illustrated by an alternate long and two short dashes line in FIG. 6A, a base material 41C is formed at the center of each of the pixels 12C in a circular pattern smaller than the pixel pitch independently for each pixel 12C. Consequently, the imaging element 11C is configured such that the filter 42C whose surface shape is convex is provided for the one pixel 12C, and light is concentrated for each pixel 12C.

For example, in the imaging element 11C, it is possible to adopt a structure using silicon dioxide as the base materials 41C, air as the inter-pixel light shielding sections 43, and silicon dioxide as the element isolation sections 31.

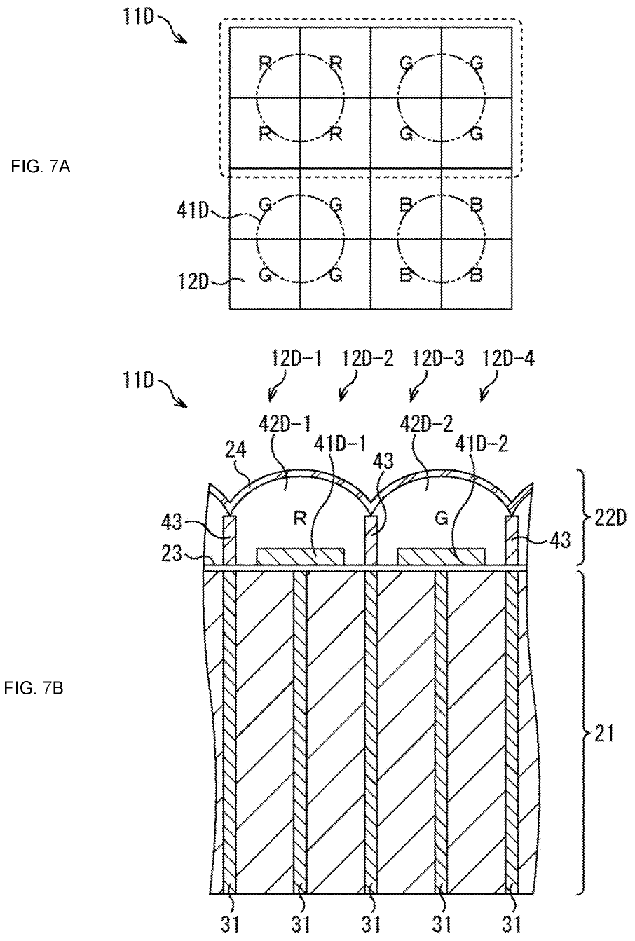

FIG. 7 depicts views illustrating an application example in which the structure of the imaging element 11 in FIG. 1 is applied to a fourth filter structure. FIG. 7A illustrates a planar layout of an imaging element 11D, and FIG. 7B illustrates a cross-sectional configuration example of four pixels 12D-1 to 12D-4 that are arranged side by side in one line of the eight pixels 12D surrounded by a dashed line illustrated in FIG. 7A.

As illustrated in FIG. 7, in the imaging element 11D, a filter layer 22D, which is a fourth filter structure, has filters 42D arranged in a pattern such that, of the four-by-four or 16 pixels 12D, the left top two-by-two pixels 12D are red (R), the right top and left bottom two-by-two pixels 12D are green (G), and the right bottom two-by-two pixels 12D are blue (B), and this pattern of the four-by-four pixels 12D is repeated.

Also, in the imaging element 11D, as illustrated by an alternate long and two short dashes line in FIG. 7A, a base material 41D is formed at the center of the region that includes two-by-two or four pixels 12D of the same color in a circular pattern smaller than the pitch of the two-by-two pixels independently for each four pixels 12D. Consequently, the imaging element 11D is configured such that the filter 42D whose surface shape is convex is provided for two-by-two or four pixels 12D, and light is concentrated for each four of these pixels 12D.

For example, in the imaging element 11D, it is possible to adopt a structure using silicon dioxide as the base materials 41D, air as the inter-pixel light shielding sections 43, and silicon dioxide as the element isolation sections 31.

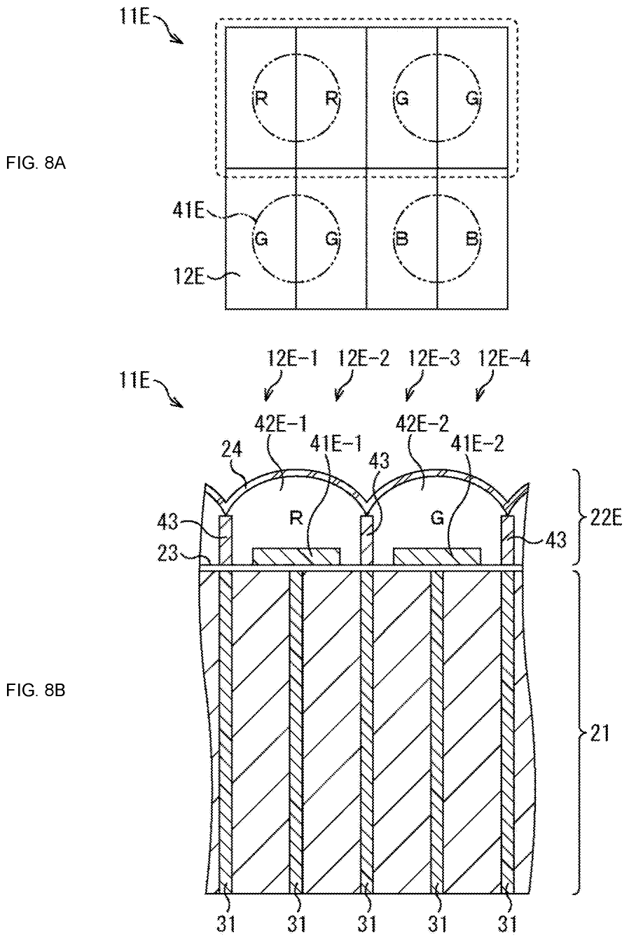

FIG. 8 depicts views illustrating an application example in which the structure of the imaging element 11 in FIG. 1 is applied to a fifth filter structure. FIG. 8A illustrates a planar layout of an imaging element 11E, and FIG. 8B illustrates a cross-sectional configuration example of four pixels 12E-1 to 12E-4 surrounded by a dashed line illustrated in FIG. 8A.

As illustrated in FIG. 8, in the imaging element 11E, rectangular pixels 12E whose vertical sides are twice as long as horizontal sides are used. Then, a filter layer 22E, which is a fifth filter structure, has filters 42E arranged in a pattern such that, of the four-by-two or eight pixels 12E, the left top two-by-one pixels 12E are red (R), the right top and left bottom two-by-one pixels 12E are green (G), and the right bottom two-by-one pixels 12E are blue (B), and this pattern of the four-by-two pixels 12E is repeated.

Also, in the imaging element 11E, as illustrated by an alternate long and two short dashes line in FIG. 8A, a base material 41E is formed at the center of the region that includes two-by-one or two pixels 12E of the same color in a circular pattern smaller than the pitch of the two-by-one pixels independently for each two pixels 12E. Consequently, the imaging element 11E is configured such that the filter 42E whose surface shape is convex is provided for the two-by-one or two pixels 12E, and light is concentrated for each two of these pixels 12E.

For example, in the imaging element 11E, it is possible to adopt a structure using silicon dioxide as the base materials 41E, air as the inter-pixel light shielding sections 43, and silicon dioxide as the element isolation sections 31.

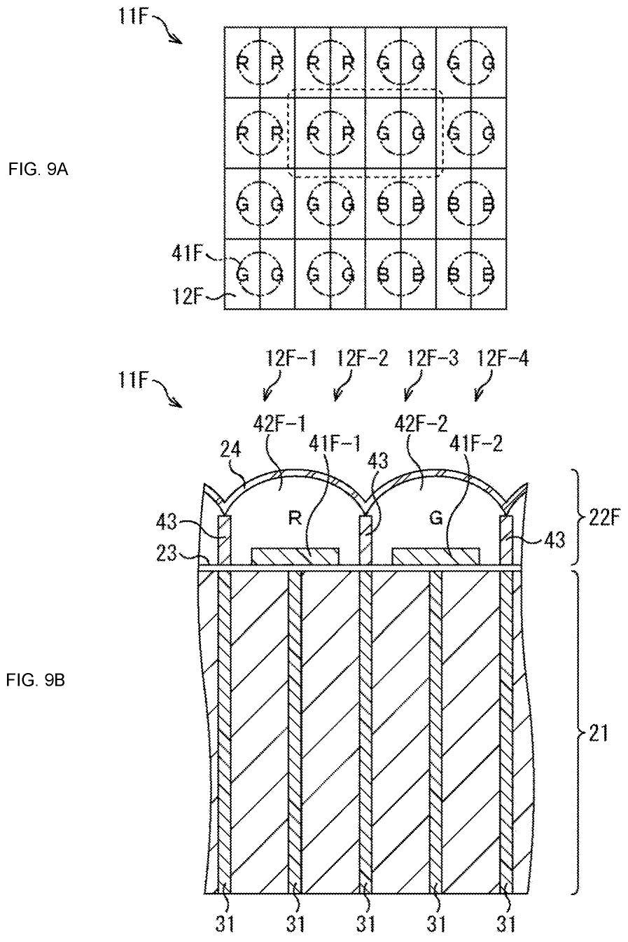

FIG. 9 depicts views illustrating an application example in which the structure of the imaging element 11 in FIG. 1 is applied to a sixth filter structure. FIG. 9A illustrates a planar layout of an imaging element 11F, and FIG. 9B illustrates a cross-sectional configuration example of four pixels 12F-1 to 12F-4 surrounded by a dashed line illustrated in FIG. 9A.

As illustrated in FIG. 9, in the imaging element 11F, rectangular pixels 12F whose vertical sides are twice as long as horizontal sides are used. Then, a filter layer 22F, which is a sixth filter structure, has filters 42F arranged in a pattern such that, for eight-by-four or 32 pixels 12F, the left top four-by-two pixels 12F are red (R), the right top and left bottom four-by-two pixels 12F are green (G), and the right bottom four-by-two pixels 12F are blue (B), and this pattern of the eight-by-four pixels 12F is repeated.

Also, in the imaging element 11F, as illustrated by an alternate long and two short dashes line in FIG. 9A, a base material 41F is formed at the center of the region that includes two-by-one or two pixels 12F of the same color in a circular pattern smaller than the pitch of the two-by-one pixels independently for each two pixels 12F. Consequently, the imaging element 11F is configured such that the filter 42F whose surface shape is convex is provided for two-by-one or two pixels 12F, and light is concentrated for each two of these pixels 12F.

For example, in the imaging element 11F, it is possible to adopt a structure using silicon dioxide as the base materials 41F, air as the inter-pixel light shielding sections 43, and silicon dioxide as the element isolation sections 31.

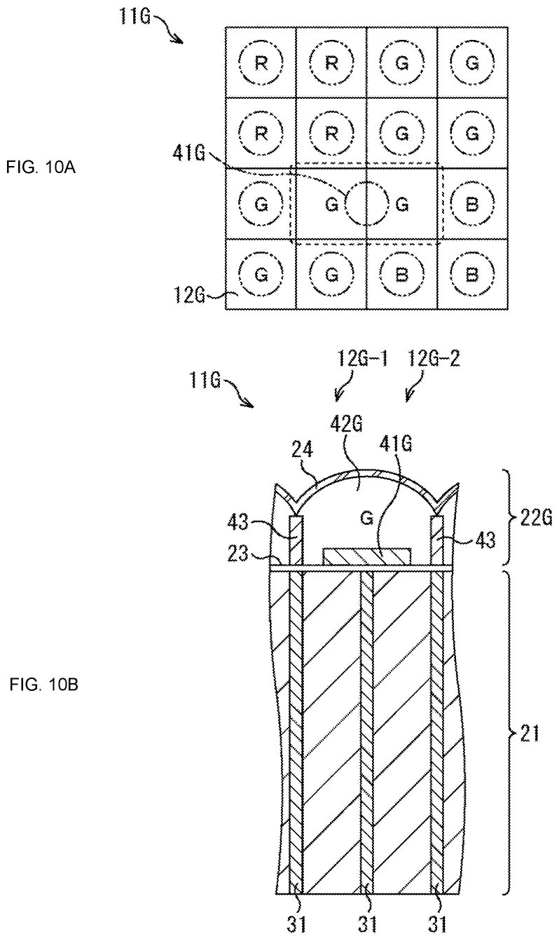

FIG. 10 depicts views illustrating an application example in which the structure of the imaging element 11 in FIG. 1 is applied to a seventh filter structure. FIG. 10A illustrates a planar layout of an imaging element 11G, and FIG. 10B illustrates a cross-sectional configuration example of two pixels 12G-1 to 12G-4 surrounded by a dashed line illustrated in FIG. 10A.

As illustrated in FIG. 10, in the imaging element 11G, a filter layer 22G, which is a seventh filter structure, has filters 42G arranged in a pattern such that, of the four-by-four or 16 pixels 12G, the left top two-by-two pixels 12G are red (R), the right top and left bottom two-by-two pixels 12G are green (G), and, of the right bottom two-by-two pixels 12G, the left top one pixel 12G is green (G) and the remaining three pixels 12G are blue (B), and this pattern of the four-by-four pixels 12G is arranged regularly in row and column directions at a given interval in place of part of the third filter structure illustrated in the above FIG. 6.

Also, although, in the imaging element 11G, as illustrated by an alternate long and two short dashes line in FIG. 10A, a base material 41F is basically formed in a circular pattern independently for each of the pixels 12G, the two-by-one green (G) pixels 12G surrounded by a dashed line are formed at the center of the region that includes these two pixels 12G in a circular pattern. For example, these two pixels 12G are used to detect phase difference for autofocus control. Consequently, in the imaging element 11G, as for the two-by-one green pixels (G) used to detect phase difference, light is concentrated by these two pixels 12G.

### <Modification Example of the Imaging Element>

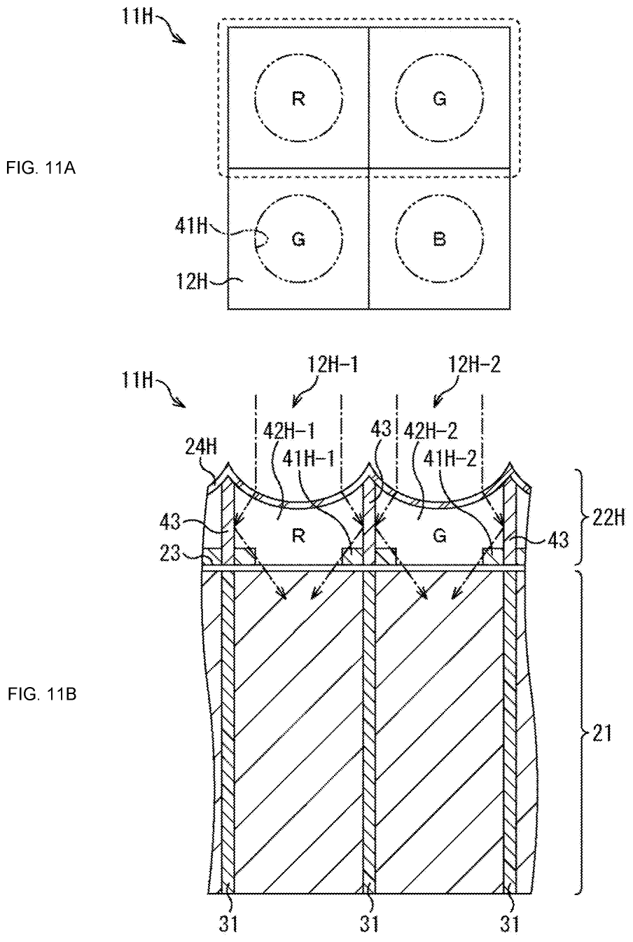

A modification example of the imaging element 11 will be described with reference to FIG. 11.

In the imaging element 11 in FIG. 1, the surface shapes of the filters 42 are formed in a convex shape. In contrast, in an imaging element 11H illustrated in FIG. 11, the surface shapes of filters 42H are formed in a concave shape.

That is, in the imaging element 11H, a base material 41H is provided independently for each pixel 12H around the pixel 12H in a pattern smaller than the pitch of the pixel 12 and so as to be circular and recessed at the center. In other words, the imaging element 11H is configured such that surrounding areas of the pixels 12H protrude because of the base materials 41H and that the base materials 41H are shaved to be recessed at the centers of the pixels 12H so that the insulating film 23 of the semiconductor substrate 21 appears.

In the imaging element 11H configured as described above, the surfaces of the filters 42H are formed in a concave shape by forming the insulating film 23 on the surface of the semiconductor substrate 21 first and then forming a film to be used as a base material over the entire surface, forming the base materials 41H by shaving the center of that film for each pixel 12H before coating with the filters 42H. Consequently, although, in the imaging element 11H, light applied to the pixels 12H spreads out as illustrated by alternate long and short dash line arrows in FIG. 11B, the light is totally reflected by the inter-pixel light shielding sections 43 and confined inside the pixels 12H.

For example, in the imaging element 11H, it is possible to adopt a structure using silicon dioxide as the base materials 41H, air as the inter-pixel light shielding sections 43, and silicon dioxide as the element isolation sections 31.

Thus, in addition to the filters 42 whose surface shapes are formed in a convex shape, the filters 42H whose surface shapes are formed in a concave shape may also be used, and it is possible to suppress color mixture better by using a configuration having surface shapes formed in a curved shape than using a configuration having surface shapes formed in a flat shape.

### <Manufacturing Method of the Imaging Element>

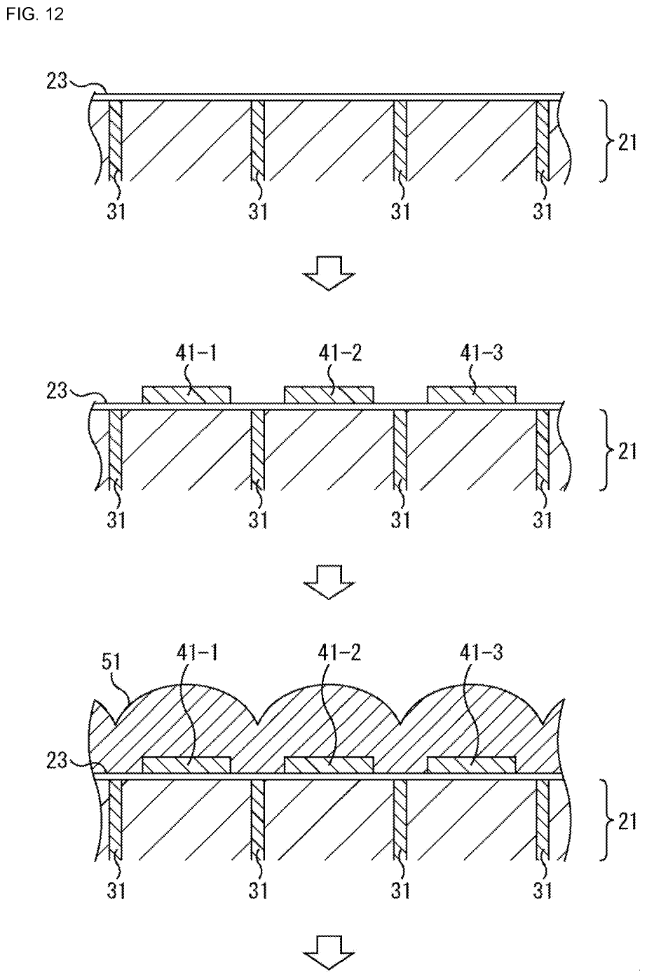

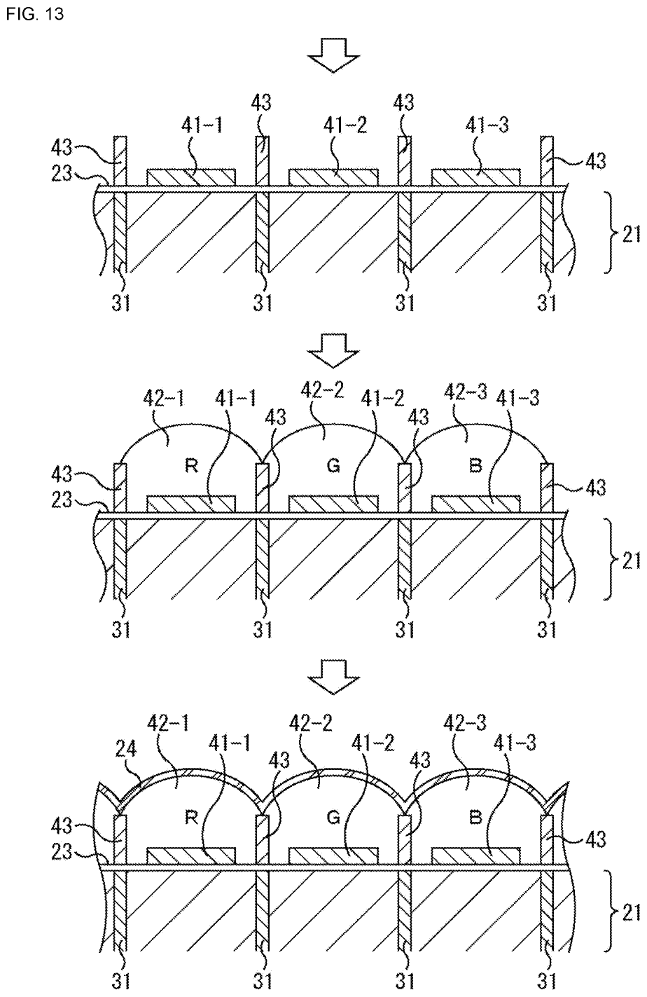

A manufacturing method of the imaging element 11 will be described with reference to FIGS. 12 and 13.

In a first process, as illustrated at a top in FIG. 12, the semiconductor substrate 21 is prepared on which the element isolation section 31 is provided between the pixels 12 and the insulating film 23 is formed on the surface.

In a second process, as illustrated at a middle in FIG. 12, the base material 41 is formed on the insulating film 23 on the surface of the semiconductor substrate 21 in an independent pattern for each pixel 12.

In a third process, as illustrated at a bottom in FIG. 12, the entire surface is coated with a low-refractive index material 51 to be used as the inter-pixel light shielding sections 43. At this time, the low-refractive index material 51 is formed such that the surface is convex for each pixel 12 because of an effect of the base materials 41.

In a fourth process, as illustrated at the top in FIG. 13, the inter-pixel light shielding sections 43 are formed by partially removing the low-refractive index material 51 so that the low-refractive index material 51 remains unremoved only between the pixels 12.

In a fifth process, as illustrated at the middle in FIG. 13, the filter 42 of each corresponding color is formed for each pixel 12 by coating. At this time, the filters 42 are formed such that the surface is convex for each pixel 12 because of the effect of the base materials 41.

In a sixth process, as illustrated at the bottom in FIG. 13, the anti-reflection film 24 is formed on the surfaces of the filters 42.

By using the manufacturing method as described above, it is possible to manufacture the imaging element 11 having the inter-pixel light shielding section 43 provided between the pixels 12, having the filters 42 whose surface shapes are convex, and being capable of reducing the occurrence of color mixture.

### <Second Configuration Example of the Imaging Element>

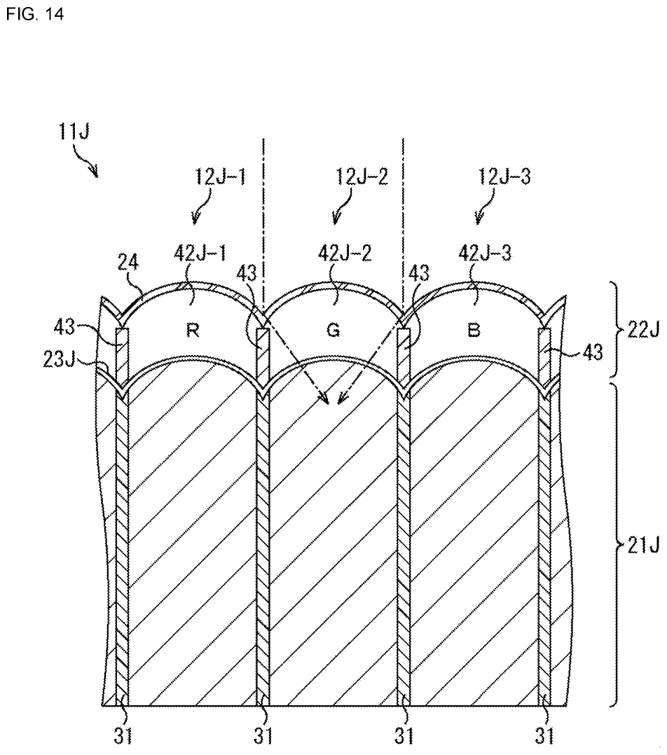

FIG. 14 is a view illustrating a configuration example of a second embodiment of the imaging element to which the present technology is applied.

In an imaging element 11J illustrated in FIG. 14, a semiconductor substrate 21J (silicon having a refractive index n=4.15 at a wavelength of 530 nm) is processed, for example, by etching so that the surface is convex for each pixel 12J. Consequently, in the imaging element 11J, the surfaces of the filters 42J are also made convex by forming the filters 42J on the semiconductor substrate 21J having such a surface shape by coating.

That is, the imaging element 11 in FIG. 1 is configured such that the surface shapes of the filters 42 are convex by providing the base materials 41 on the surface of the semiconductor substrate 21. In contrast, the imaging element 11J is configured such that the surface shapes of the filters 42J are convex by making the surface of the semiconductor substrate 21J convex.

Also, in the imaging element 11J having such a configuration, it is also possible to reduce the occurrence of color mixture and increase the quantum efficiency QE by concentrating light for each pixel 12J by using the filters 42J whose surface shapes are convex as in the imaging element 11 in FIG. 1.

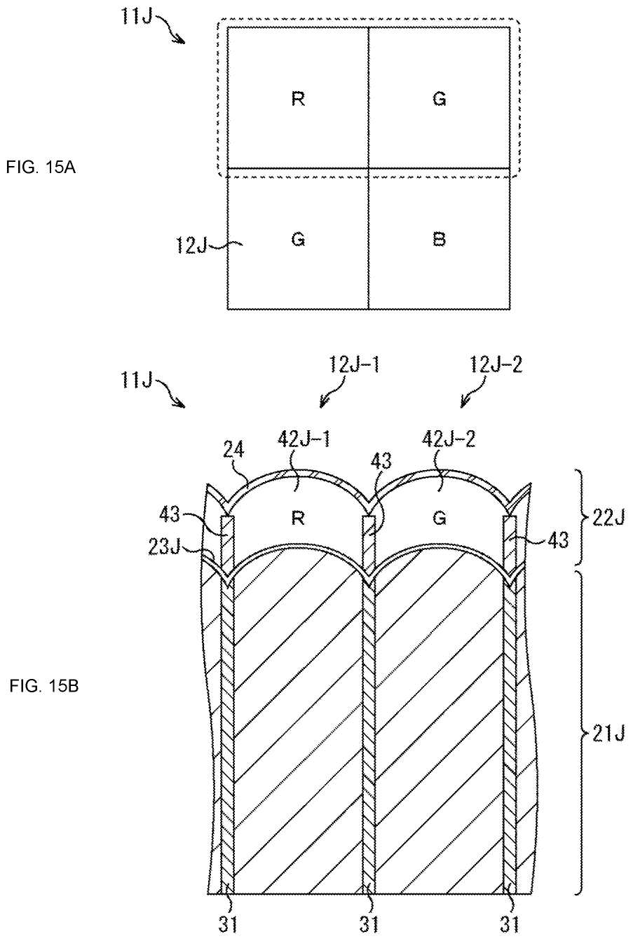

FIG. 15 depicts views illustrating an application example in which the structure of the imaging element 11J in FIG. 14 is applied to what is called a Bayer pattern filter structure. FIG. 15A illustrates a planar layout of the imaging element 11J, and FIG. 15B illustrates a cross-sectional configuration example of two pixels 12J-1 and 12J-2 surrounded by a dashed line illustrated in FIG. 15A.

As in FIG. 4, the filter structure illustrated in FIG. 15 has filters 42J arranged in a pattern such that the left top pixel 12J is red (R), the right top and left bottom pixels 12J are green (G), and the right bottom pixel 12J is blue (B), and this pattern of the two-by-two pixels 12J (what is called a Bayer pattern) is repeated.

For example, in the imaging element 11J, it is possible to adopt a structure using air as the inter-pixel light shielding sections 43 and silicon dioxide as the element isolation sections 31.

### <Manufacturing Method of the Imaging Element>

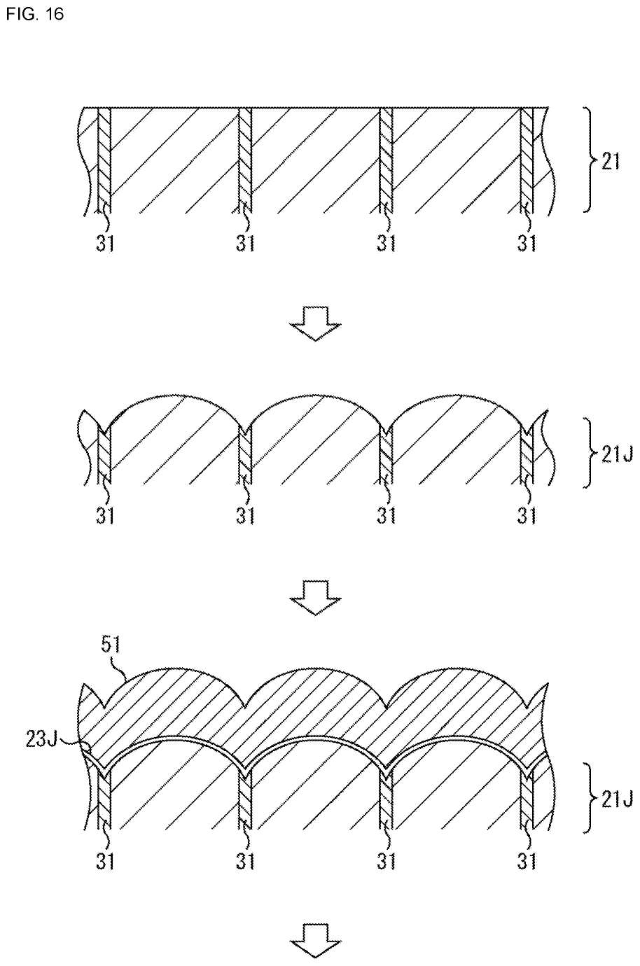

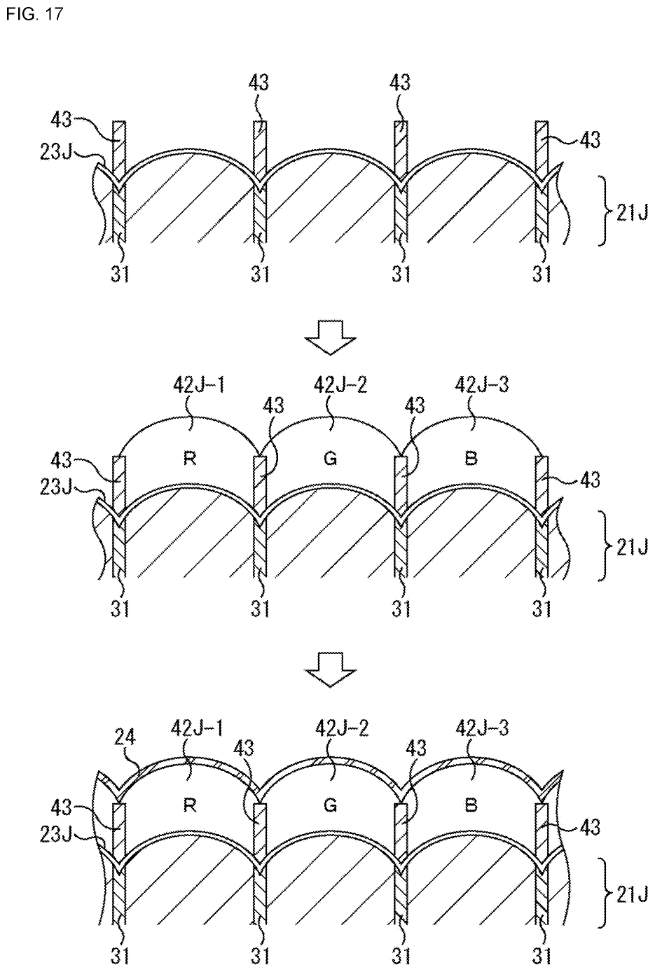

A manufacturing method of the imaging element 11J will be described with reference to FIGS. 16 and 17.

In an eleventh process, as illustrated at the top in FIG. 16, a semiconductor substrate 21 is prepared on which the element isolation section 31 is provided between the pixels 12.

In a twelfth process, as illustrated at the middle in FIG. 16, the semiconductor substrate 21J is processed, for example, by etching so that the surface is convex.

In a thirteenth process, as illustrated at the bottom in FIG. 16, the insulating film 23 is formed on the surface of the semiconductor substrate 21J first, and then the entire surface is coated with the low-refractive index material 51 to be used as the inter-pixel light shielding section 43. At this time, the low-refractive index material 51 is formed such that the surface is convex for each pixel 12J because of the effect of the surface of the semiconductor substrate 21J being convex.

In a fourteenth process, as illustrated at the top in FIG. 17, the inter-pixel light shielding sections 43 are formed by partially removing the low-refractive index material 51 such that the low-refractive index material 51 remains unremoved only between the pixels 12J.

In a fifteenth process, as illustrated at the middle in FIG. 17, the filter 42J of each corresponding color is formed for each pixel 12J by coating. At this time, the filters 42J are formed such that the surface is convex for each pixel 12J because of the effect of the surface of the semiconductor substrate 21J being convex.

In a sixteenth process, as illustrated at the bottom in FIG. 17, the anti-reflection film 24 is formed on the surfaces of the filters 42J.

By using the manufacturing method described above, it is possible to manufacture the imaging element 11J having the inter-pixel light shielding section 43 provided between the pixels 12, having the filters 42J whose surface shapes are convex, and being capable of reducing the occurrence of color mixture.

### <Configuration Example of the Electronic Equipment>

The imaging element 11 as described above is applicable to various types of electronic equipment including an imaging system such as a digital still camera and a digital video camera, mobile phones having an imaging function, or other equipment having an imaging function.

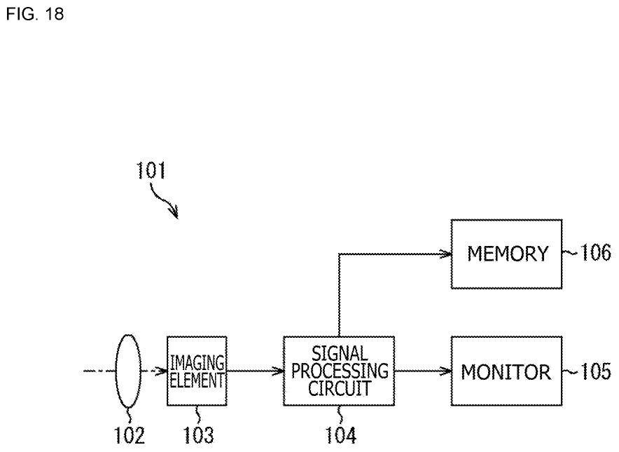

FIG. 18 is a block diagram illustrating a configuration example of an imaging apparatus installed in electronic equipment.

As illustrated in FIG. 18, an imaging apparatus 101 includes an optics 102, an imaging element 103, a signal processing circuit 104, a monitor 105, and a memory 106 and is capable of capturing still images and videos.

The optics 102 includes one or a plurality of lenses, guides image light (incident light) from a subject to the imaging element 103, and forms an image on a light-receiving surface (sensor section) of the imaging element 103.

The above imaging element 11 is used as the imaging element 103. Electrons are accumulated in the imaging element 103 for a certain period of time according to the image formed on the light-receiving surface via the optics 102. Then, a signal appropriate to the electrons accumulated in the imaging element 103 is supplied to the signal processing circuit 104.

The signal processing circuit 104 performs various types of signal processing on the pixel signal output from the imaging element 103. The image (image data) obtained as a result of signal processing performed by the signal processing circuit 104 is supplied and displayed on the monitor 105 and is supplied and stored (recorded) in the memory 106.

In the imaging apparatus 101 configured as described above, it is possible, for example, to capture images of higher quality with no color mixture by using the above imaging element 11.

### <Usage Example of the Image Sensor>

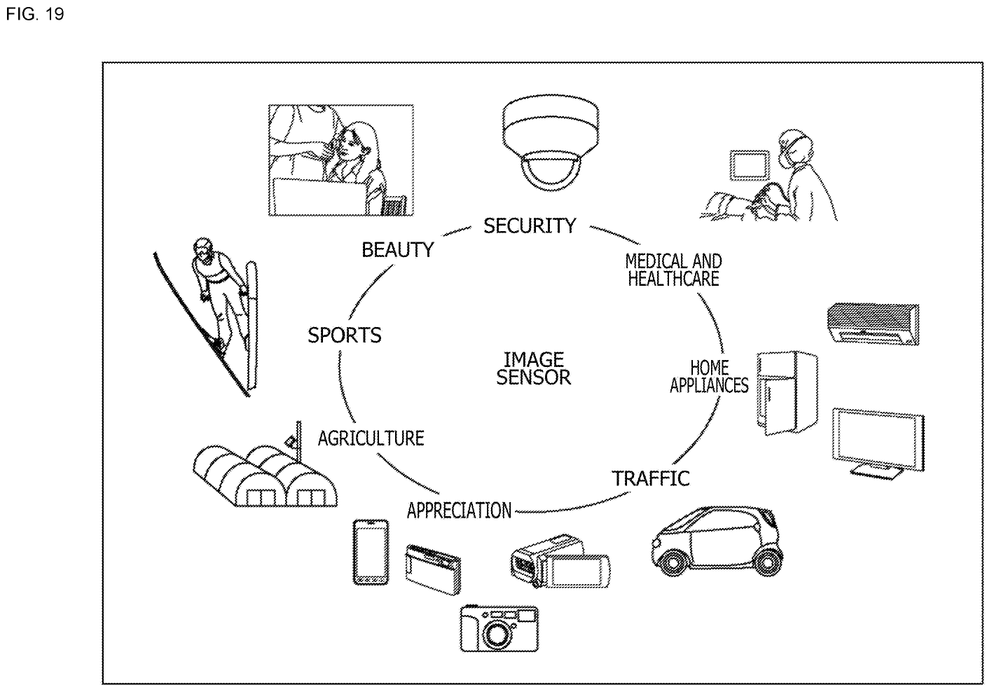

FIG. 19 is a diagram illustrating a usage example of using the above image sensor (imaging element).

It is possible to use the above image sensor, for example, in various cases where light such as visible light, infrared light, ultraviolet light, and X-ray are sensed as described below.
Apparatuses that capture images provided for appreciation uses such as a digital camera and portable equipment having a camera function
Apparatuses provided for traffic uses such as vehicle-mounted sensors that capture images in front and back, around, and inside automobiles, and the like for safe driving such as automatic stop and for recognition of drivers' conditions, surveillance cameras for monitoring traveling vehicles and roads, distance measuring sensors that measure distances between vehicles, and the like
Apparatuses provided for home appliances such as TV sets, refrigerators, and air conditioners for capturing users' gestures and operating equipment according to their gestures
Apparatuses provided for medical and healthcare uses such as endoscopes and apparatuses for capturing blood vessels by receiving infrared light
Apparatuses provided for security uses such as surveillance cameras for crime prevention applications, cameras for individual authentication applications, and the like
Apparatuses for beauty uses such as skin measuring instruments for capturing skin, microscopes for capturing scalp, and the like
Apparatuses provided for sports uses such as action cameras and wearable cameras for sports applications and the like
Apparatuses for agricultural uses such as cameras for monitoring farm and crop conditions

### <Combination Example of Configurations>

It is noted that the present technology can also take the following configurations.
(1)
A solid-state imaging element including:
a semiconductor substrate having a photoelectric conversion section provided for each pixel; and
a filter layer provided on a light-receiving side of the semiconductor substrate, in which,
in the filter layer,
a filter whose surface shape is formed in a curved shape is provided for each of the pixels, and
an inter-pixel light shielding section including a low-refractive index material having a refractive index lower than that of the filter is provided between the pixels.
(2)
The solid-state imaging element according to (1) above, further including:
base materials provided in a pattern smaller than a pixel pitch of a given number of pixels so as to protrude relative to an insulating film formed on a surface of the semiconductor substrate, in which
the surface shapes of the filters are formed in a convex shape by stacking the filters on the base materials.
(3)
The solid-state imaging element according to (2) above, in which
a refractive index of the base materials is equal to or lower than that of the semiconductor substrate and equal to or higher than that of the inter-pixel light shielding section.
(4)
The solid-state imaging element according to (2) or (3) above, in which
a height of the base materials is equal to or smaller than that of the inter-pixel light shielding section.
(5)
The solid-state imaging element according to any one of (1) to (4) above, in which
the filter layer has the filters arranged in a pattern such that, of the four-by-four or 16 pixels, the left top two-by-two pixels are red, the right top and left bottom two-by-two pixels are green, and the right bottom two-by-two pixels are blue, and this pattern of the four-by-four pixels is repeated.
(6)
The solid-state imaging element according to (5) above, in which
the base materials are arranged in a pattern smaller than a pixel pitch of one pixel and at a center of the pixel.
(7)
The solid-state imaging element according to (5) above, in which
the base materials are formed in a pattern smaller than the pixel pitch of the two-by-two or four pixels and at a center of a region that includes the two-by-two or four pixels of the same color.
(8)
The solid-state imaging element according to (1) above, further including:
base materials provided relative to an insulating film formed on a surface of the semiconductor substrate, in a pattern smaller than the pixel pitch of the pixel so as to be recessed at a center of the pixel, in which
the surface shapes of the filters are formed in a concave shape by stacking the filters on the base materials.
(9)
The solid-state imaging element according to (1) above, in which
a surface of the semiconductor substrate is formed in a convex shape for each of the pixels, and
the surface shapes of the filters are formed in a convex shape by stacking the filters on the semiconductor substrate.
(10)
A manufacturing method of a solid-state imaging element, the solid-state imaging element including
a semiconductor substrate having a photoelectric conversion section provided for each pixel, and
a filter layer provided on a light-receiving side of the semiconductor substrate, the manufacturing method including:
in the filter layer,
providing a filter whose surface shape is formed in a curved shape for each of the pixels; and
providing an inter-pixel light shielding section including a low-refractive index material having a refractive index lower than that of the filter between the pixels.
(11)
Electronic equipment including:
a solid-state imaging element including
a semiconductor substrate having a photoelectric conversion section provided for each pixel, and
a filter layer provided on a light-receiving side of the semiconductor substrate, in which
in the filter layer,
a filter whose surface shape is formed in a curved shape is provided for each of the pixels, and
an inter-pixel light shielding section including a low-refractive index material having a refractive index lower than that of the filter is provided between the pixels.

It should be noted that the present embodiments are not limited to the above embodiments and can be modified in various ways without departing from the gist of the present disclosure. Also, advantageous effects described in the present specification are merely illustrative and not limited, and there may be other advantageous effects.

### REFERENCE SIGNS LIST

11: Imaging element
12: Pixel
21: Semiconductor substrate
22: Filter layer
23: Insulating film
24: Anti-reflection film
31: Element isolation section
41: Base material
42: Filter
43: Inter-pixel light shielding section
51: Low-refractive index material

1. A solid-state imaging element comprising:
a semiconductor substrate having a photoelectric conversion section provided for each pixel; and
a filter layer provided on a light-receiving side of the semiconductor substrate, wherein,
in the filter layer,
a filter whose surface shape is formed in a curved shape is provided for each of the pixels, and
an inter-pixel light shielding section including a low-refractive index material having a refractive index lower than that of the filter is provided between the pixels.

2. The solid-state imaging element according to claim 1, further comprising:
base materials provided in a pattern smaller than a pixel pitch of a given number of pixels so as to protrude relative to an insulating film formed on a surface of the semiconductor substrate, wherein
the surface shapes of the filters are formed in a convex shape by stacking the filters on the base materials.

3. The solid-state imaging element according to claim 2, wherein
a refractive index of the base materials is equal to or lower than that of the semiconductor substrate and equal to or higher than that of the inter-pixel light shielding section.

4. The solid-state imaging element according to claim 2, wherein
a height of the base materials is equal to or smaller than that of the inter-pixel light shielding section.

5. The solid-state imaging element according to claim 2, wherein
the filter layer has the filters arranged in a pattern such that, of the four-by-four or 16 pixels, the left top two-by-two pixels are red, the right top and left bottom two-by-two pixels are green, and the right bottom two-by-two pixels are blue, and this pattern of the four-by-four pixels is repeated.

6. The solid-state imaging element according to claim 5, wherein
the base materials are arranged in a pattern smaller than a pixel pitch of one pixel and at a center of the pixel.

7. The solid-state imaging element according to claim 5, wherein
the base materials are formed in a pattern smaller than the pixel pitch of the two-by-two or four pixels and at a center of a region that includes the two-by-two or four pixels of a same color.

8. The solid-state imaging element according to claim 1, further comprising:
base materials provided relative to an insulating film formed on a surface of the semiconductor substrate, in a pattern smaller than the pixel pitch of the pixel so as to be recessed at a center of the pixel, wherein
the surface shapes of the filters are formed in a concave shape by stacking the filters on the base materials.

9. The solid-state imaging element according to claim 1, wherein
a surface of the semiconductor substrate is formed in a convex shape for each of the pixels, and
the surface shapes of the filters are formed in a convex shape by stacking the filters on the semiconductor substrate.

10. A manufacturing method of a solid-state imaging element, the solid-state imaging element including
a semiconductor substrate having a photoelectric conversion section provided for each pixel, and
a filter layer provided on a light-receiving side of the semiconductor substrate, the manufacturing method comprising:
in the filter layer,
providing a filter whose surface shape is formed in a curved shape for each of the pixels; and
providing an inter-pixel light shielding section including a low-refractive index material having a refractive index lower than that of the filter between the pixels.

11. Electronic equipment comprising:
a solid-state imaging element including
a semiconductor substrate having a photoelectric conversion section provided for each pixel, and
a filter layer provided on a light-receiving side of the semiconductor substrate, wherein
in the filter layer,
a filter whose surface shape is formed in a curved shape is provided for each of the pixels, and
an inter-pixel light shielding section including a low-refractive index material having a refractive index lower than that of the filter is provided between the pixels.
